(19) United States
(12) Patent Application Publication
(10) Pub. No.: US 2026/0068100 A1
(43) Pub. Date: Mar. 5, 2026

(54) FLUID MANAGEMENT MECHANISM

(71) Applicant: Dell Products L.P., Round Rock, TX (US)

(72) Inventor: TIMOTHY ALLEN SHEDD, Lithia, FL (US)

(21) Appl. No.: 18/820,568

(22) Filed: Aug. 30, 2024

(51) Int. Cl. H05K 7/20

(52) U.S. Cl. CPC H05K 7/20627; H05K 7/20272; H05K 7/20281

(57) ABSTRACT

Methods, systems, and devices for managing a data processing system that provides computer implemented services are disclosed. To provide the computer implemented services, a system may include a chassis adapted to house hardware components of the data processing system. To dissipate heat generated by the hardware components, the system may further include a quick connection adapted to place the chassis in fluid communication with a manifold through which cooling fluid flows, a fluid management mechanism adapted to, while the chassis is positioned in the rack system at a predetermined location, reversibly reposition the quick connection with respect to the chassis to establish the fluid communication or terminate the fluid communication.

### FIELD

Embodiments disclosed herein relate generally to management of data processing systems. More particularly, embodiments disclosed herein relate to systems and methods for mitigating damage to data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIGS. 2A-2G show diagrams illustrating a fluid management mechanisms in accordance with an embodiment.

FIG. 3 shows a flow diagram illustrating a method for managing fluid used with a system in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing data processing systems that may provide, at least in part, computer implemented services. The computer implemented services may be provided to any type and/or number of other devices and/or users of the data processing systems. Furthermore, the provided computer implemented services may be of any quantity and/or type of such services.

To provide the computer implemented services, data processing systems may include hardware components. For example, operation of these hardware components may facilitate various functionalities of a data processing system, thereby causing the data processing system to provide the computer implemented services.

However, the operation of said hardware components may generate heat. To regulate this heat, a liquid cooling system may be used to circulate a cooling liquid to dissipate at least a portion of the heat generated by the hardware components.

However, by circulating the cooling liquid (and/or otherwise have liquid within the system), a likelihood of liquid damage may be increased within the system. For example, should the liquid cooling system leak at least a portion of the liquid, the hardware components may be vulnerable to liquid damage.

Consequently, such liquid damage may negatively impact the operation of the hardware components. In turn, this damage may also negatively impact the computer implemented services to be provided by the system.

To decrease the likelihood of these negative impacts, a fluid management mechanism may be used to establish fluid communication or terminate the fluid communication between the chassis and manifold through which cooling fluid for heat dissipation flows from. Additionally, should connection and/or reconnection of the quick connection be desired and/or required, this fluid management mechanism may also be used to do so.

For example, this fluid management mechanism may be used with a rack system in which one or more chassis are mounted, the manifold providing the cooling fluid to each of the chassis and thus, being in fluid communication with each of the chassis. This fluid communication may be facilitated by quick connections and based on an identification of a leak within the system, the fluid management mechanism may allow for the quick connections to be severed, thereby mitigating damage caused by a leak by stopping circulation of additional cooling fluid from the manifold. Once repaired, the fluid management mechanism may allow for the quick connections to be reconnected, thereby reestablishing fluid communication.

In an embodiment, a rack system is provided.

This rack system may include a chassis adapted to house hardware components of a data processing system that provides computer implemented services; a quick connection adapted to place the chassis in fluid communication with a manifold through which cooling fluid flows; and a fluid management mechanism adapted to while the chassis is positioned in the rack system at a predetermined location: reversibly reposition the quick connection with respect to the chassis to establish the fluid communication or terminate the fluid communication.

The fluid management mechanism may include a horizontal tube that is in fluid communication with the manifold; and is adapted to move between two positions to facilitate repositioning of the quick connection.

While the horizontal tube is in a first position of the two positions and the chassis is in in the predetermined position, the horizontal tube may be in fluid communication with the quick connection, and while the horizontal tube is not in the first position and the chassis is in the predetermined position, the horizontal tube may not be in fluid communication with the quick connection.

The fluid management mechanism may further include a rotating member that is mechanically coupled to the horizontal tube to reposition between the two positions; and an actuator adapted to apply force to the rotating member that causes the rotating member to rotate in one of two directions, when rotating in a first of the two directions the horizontal tube is moved toward the chassis while the chassis is in the predetermined position and when rotating in a second of the two directions the horizontal tube is moved away from the chassis while the chassis is in the predetermined position.

The fluid management mechanism may further include a second actuator adapted to apply a second force to the rotating member that causes the rotating member to rotate in the one of the two directions.

The actuator and the second actuator may be redundantly mechanically coupled to the rotating member to improve a likelihood of the rack system being able to stop occurrences of leaks of the cooling fluid from continuing.

Reversibly repositioning the quick connection may include obtaining, from a management entity tasked with managing the rack system, a control signal based on a likelihood of presence of a leak of the cooling fluid in the chassis; in a first instance of the obtaining where the likelihood indicates that a leak of the cooling fluid is ongoing disconnecting a connection to terminate the fluid communication; and in a second instance of the obtaining where the likelihood indicates that a leak of the cooling fluid is not ongoing maintaining or reconnecting the connection to facilitate the fluid communication.

The rack system may further include a leak sensor positioned in the interior of the chassis, adapted to detect leaks due to the cooling fluid, and operably connected to the management entity to activate the actuator when a leak is present.

The rack system may further include a seal plate that may include a first sealing surface to seal the seal plate to the vertical tube and a second sealing surface to seal the seal plate to a slidable tube that connects the quick connection to the vertical tube.

The cooling fluid may flow through an interior of the chassis to cool a hardware component that contributes to the computer implemented services.

In an embodiment, a fluid management mechanism for use with a data processing system is provided as discussed above.

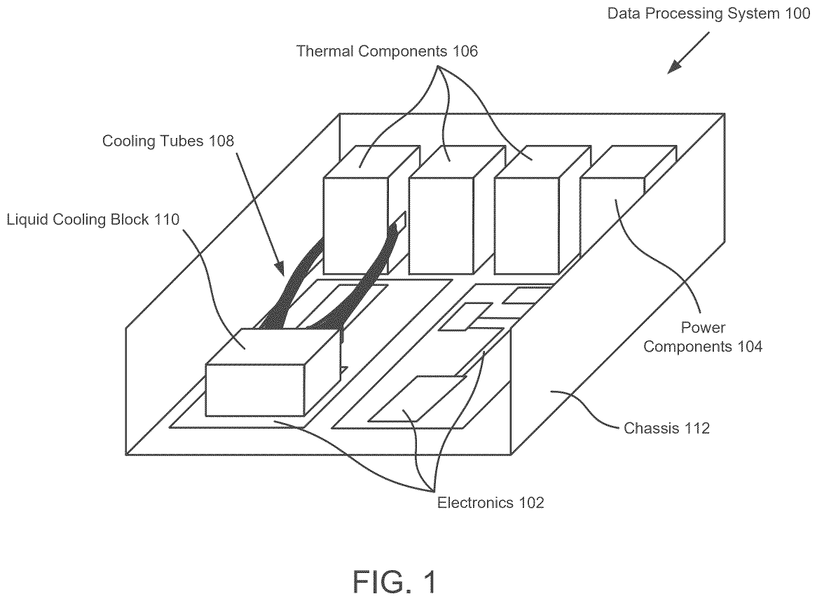

Turning to FIG. 1, a block diagram illustrating a system in accordance with an embodiment is shown. The system shown in FIG. 1 may be a distributed system that provides for management of data processing systems that may provide, at least in part, computer implemented services.

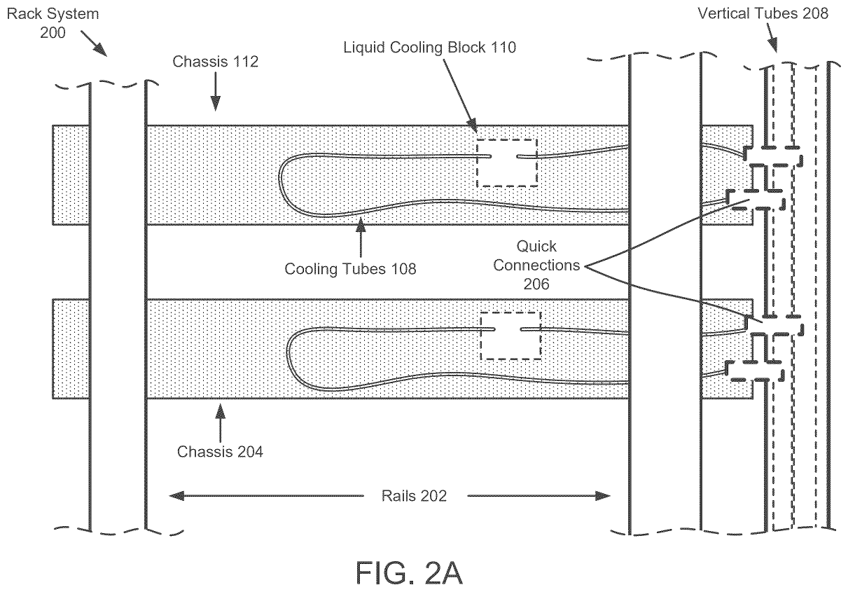

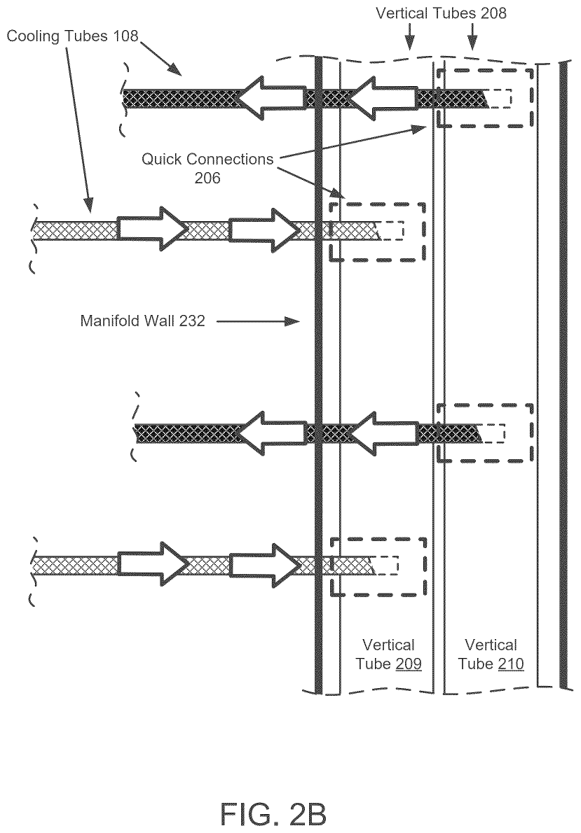

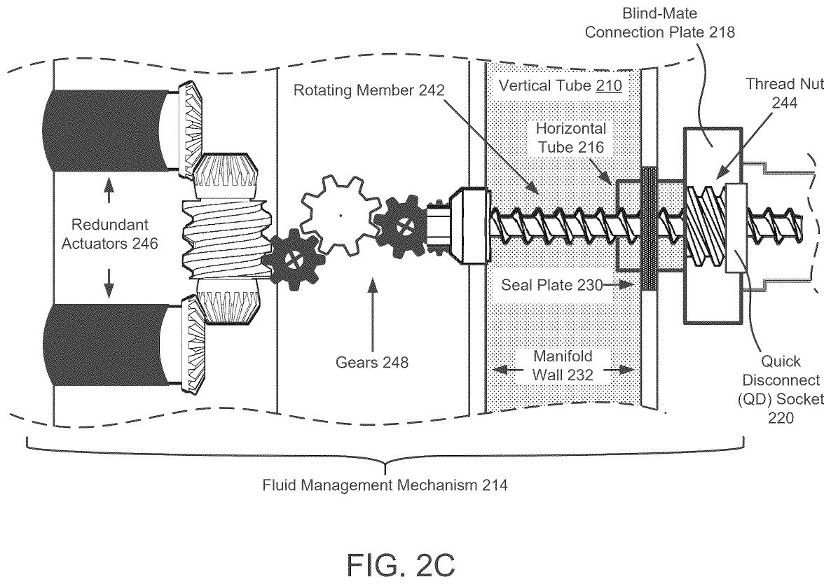

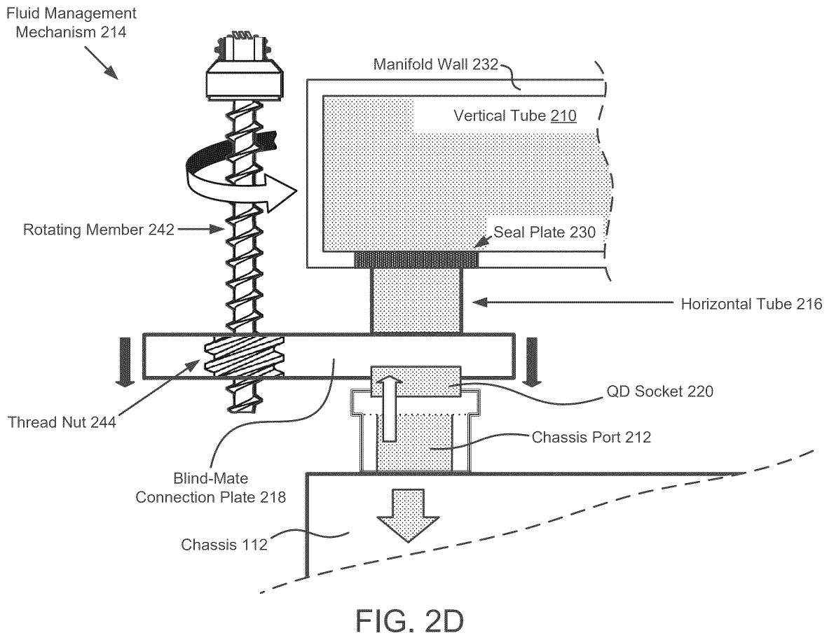

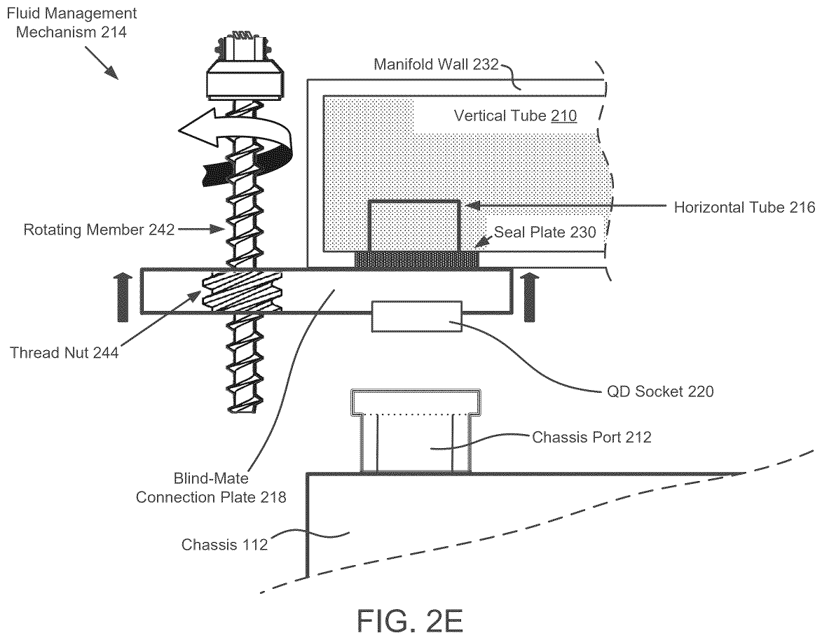

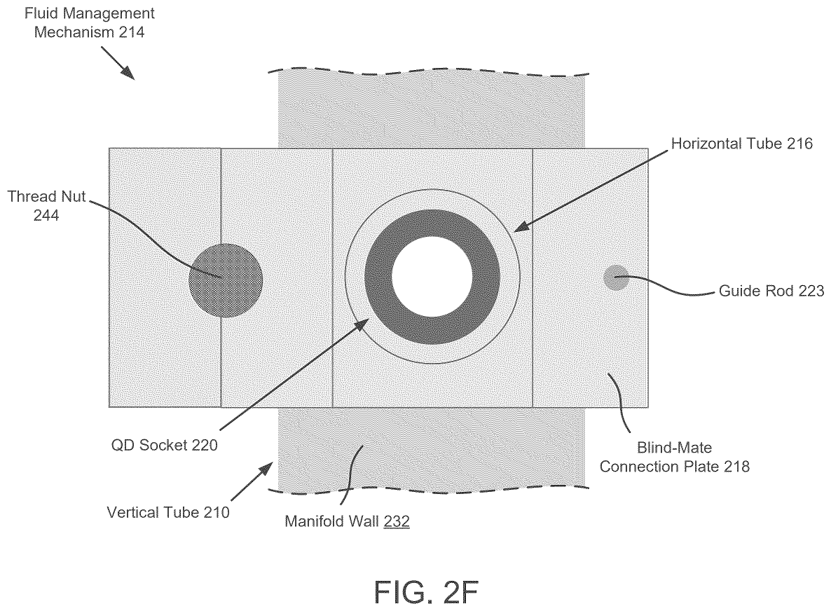

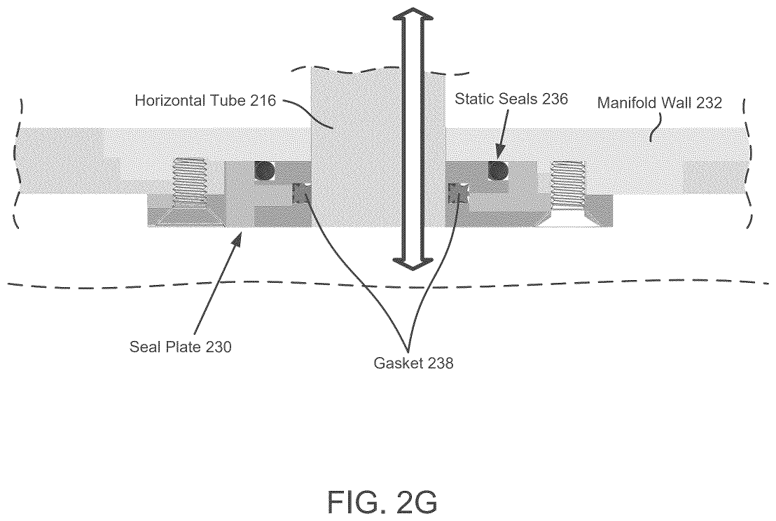

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices positioned with a rack mount chassis system in which data processing system 100 may be placed (e.g., as shown in FIG. 2A).

Other types of computer implemented services may be provided by the system shown in FIG. 1 without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services.

For example, to facilitate the various functionalities, a hardware component may transmit data with other devices via various avenues of communication. For example, such avenues of communication may depend on physical operable connections that directly connect multiple hardware components to one another. To provide the above noted functionality, the system of FIG. 1 may include data processing system 100.

Data processing system 100 may include electronics 102, chassis 112, power components 104, and thermal components 106. Each of these is discussed below.

Electronics 102 may include at least a portion of the any number of hardware components, and as noted above, may provide computer implemented services. Hardware components of electronics 102 may be positioned on circuit cards and may generate heat while operating. Circuit cards may be pieces of circuit boards.

Electronics 102 and/or any other components of the any number of hardware components of data processing system 100 may be positioned in chassis 112. Chassis 112 may include an enclosure in which physical structures of electronics 102 (e.g., processors, memory, etc.), and/or other components of data processing system 100 may be positioned. For example, chassis 112 may facilitate placement and management of electronics 102 and/or other components (e.g., power components 104 and/or thermal components 106) in a computing environment such as those discussed below.

Power components 104 may power the any number of hardware components of data processing system 100. For example, power components 104 may be implemented using power supplies. Furthermore, operation of these power supplies may also contribute to the generation of heat. If left unregulated, this generation of heat may increase the likelihood of damage, as previously mentioned.

To manage the heat, data processing system 100 may include a liquid cooling system that is at least partially housed by chassis 112. This liquid cooling system may use (e.g., may include) a number of cooling components such as thermal components 106, and/or any other cooling components not shown in the system of FIG. 1.

It will be appreciated that for additional discussion of at least a portion of the any other cooling components not shown in the system of FIG. 1, refer to FIGS. 2A-2B.

Thermal components 106 may thermally manage any of the components of data processing system 100. For example, thermal components 106 may include thermal components such as cooling fans, coolant reservoirs and/or receiving elements for coolant, coolant (e.g., a cooling fluid), circulation pumps, manifolds or other types of flow control components, and/or other components to facilitate performance of liquid-based cooling of at least some of electronics 102. For example, thermal components 106 may be used with cooling tubes 108 and liquid cooling block 110, each of which is discussed below.

Liquid cooling block 110 may facilitate a dissipation of heat generated by, for example, electronics 102 by circulating the cooling fluid via cooling tubes 108. To provide its functionality, liquid cooling block 110 operate as a heat sink for some electronic components. For example, liquid cooling block 110 may be placed with an electronic component to (i) receive heat generated by the electronic components, and (ii) dissipate the received heat into cooling fluid circulated through liquid cooling block 110. While providing its functionality, a transference of at least a portion of the generated heat may be facilitated.

For example, the cooling fluid, confined to a flow path that circulates through a loop of a liquid cooling system (e.g., cooling tubes 108, liquid cooling block 110, external components such as large scale coolant chillers, flow controllers, etc.), may be placed in thermal communication with a hardware component of electronics 102 generating the heat when the cooling fluid is flowing through a portion of the loop that is proximate to the hardware component. By being in this thermal communication, the cooling fluid may be heated while the heat generated by the hardware component is dissipated into the cooling fluid thereby regulated the temperature of the hardware component.

Due to the cooling fluid circulating through liquid cooling block 110, this heated cooling fluid may flow to another portion of the loop (e.g., external to data processing system 100 such as a large scale chiller). Thus, the cooling fluid may be cyclically heated and cooled as the cooling fluid continues to flow through the loop, thereby contributing to the dissipation of heat generated by the any number of hardware components of electronics 102.

For example, the cooling liquid may be directed through an interior of liquid cooling block 110 and through a first portion of cooling tubes 108. Cooling tubes 108 may further facilitate the circulation by directing the cooling liquid, for example, to other cooling blocks proximate to other hardware components of electronics 102 to facilitate cooling of multiple hardware components of electronics 102. To do so, cooling tubes 108 may include hollow, tubular structures in which liquid may flow through. For example, the cooling liquid, once cooled by external chillers, may then be further circulated through a second portion of cooling tubes 108 to direct the cooling liquid back through the liquid cooling block 110 to facilitate transference of additional heat generated by electronics 102.

However, by using the liquid cooling system discussed above, a likelihood of physically damaging the any number of hardware components (e.g., should a leak in liquid cooling block 110 and/or cooling tubes 108 occur) may be increased due to the presence of the cooling fluid. For example, if liquid cooling block 110 and/or cooling tubes 108 begin to leak, at least a portion of the cooling fluid may no longer be confined to the flow path that circulates through the loop of the liquid cooling system.

Consequently, should the any number of hardware components become exposed to liquid (e.g., the cooling fluid), functionality of the any number of hardware components may be negatively impacted, thereby negatively impacting the computer implemented services, previously discussed.

To mitigate this exposure, thereby decreasing the likelihood of damaging the hardware components, a fluid management mechanism may be used with a fluid distribution system. This fluid management mechanism may facilitate reversible disconnection of quick connections used in, for example, blind-mate connections between a chassis (e.g., 112) and, for example, a manifold (not shown in FIG. 1) through which cooling fluid flows and is provided to and received from the liquid cooling system. Furthermore, this fluid management mechanism may facilitate reversible disconnections of (and maintain inaccessibility to) the quick connections based on any identified leaks in the system (and/or reconnection). For additional information regarding the fluid distribution system and/or the quick connections of the rack system used with the fluid management mechanism, refer to FIGS. 2A-2B.

Thus, additional leaked cooling fluid may be prevented from escaping into an interior of the chassis should the leak be present in the chassis. In doing so, the likelihood of negatively impacting the hardware components, their functionalities, and the computer implemented services that depend on these functionalities, may be increased. Furthermore, fluid communication may be successfully reestablished based on successful repair of the leak, thus allowing the computer implemented services to be provided.

For additional information regarding the fluid management mechanism (e.g., 214, FIG. 2C), continue to the descriptions of FIGS. 2A-2G, further below.

While illustrated in FIG. 1 with a limited number of specific components, a data processing system may include additional, fewer, and/or different components without departing from embodiments disclosed herein.

To further clarify embodiments disclosed herein, diagrams illustrating examples of data processing systems (and portions thereof) in accordance with embodiments are shown in FIGS. 2A-2G.

Turning to FIG. 2A, a diagram illustrating a side view of a rack system (e.g., 200) in accordance with an embodiment is shown (e.g., a front side and rear side of rack system 200 being depicted on a left-hand side and on a right-hand side, respectively, of the page).

Rack system 200 may be used to position and/or otherwise manage various chassis with regard to one another. To do so, rack system 200 may include rails 202 to fixedly secure each chassis to a respective height between the rails. For example, a second chassis may be positioned just under data processing system 100, separated by a distance along the length of rails 202.

Rack system 200 may include any number of mounted data processing systems. As shown in FIG. 2A, for example, data processing system 100 that is discussed with regard to FIG. 1 (e.g., illustrated with chassis 112 and liquid cooling block 110), the second data processing system (e.g., illustrated with chassis 204) positioned below data processing system 100, and/or any other data processing system not shown in FIG. 2A may be mounted on rack system 200.

As previously discussed, hardware components of data processing system 100 may generate heat during their operation. Such generation of heat may also occur in any other chassis mounted on rack system 200. This heat may be regulated (e.g., dissipated) by any number of liquid cooling systems (e.g., the liquid cooling system of data processing system 100, shown in FIG. 1).

Cooling fluid (e.g., as discussed with regard to FIG. 1) circulated through loops of the any number of liquid cooling systems may be provided by a fluid distribution system. This fluid distribution system may include a manifold positioned with rack system 200. For example, a manifold, depicted using vertical tubes 208 in FIG. 2A, may provide liquid cooling system loops of various mounted (to rack system 200) chassis (e.g., chassis 112 and 204) with cooling fluid. This manifold may also allow for cooling fluid to leave the chassis.

To provide the chassis with the cooling fluid, fluid communication may be established between each of the mounted chassis and vertical tubes 208. To establish this fluid communication, the system of FIG. 2A may include quick connections 206, discussed below with regard to FIG. 2B.

Turning to FIG. 2B, a diagram illustrating an expanded view of a portion of the manifold discussed with regard to FIG. 2A in accordance with an embodiment is shown.

As previously discussed, the manifold (e.g., vertical tubes 208) may provide cooling fluid to various chassis and/or may allow cooling fluid to leave these chassis. As shown in FIG. 2B, for example, the providing and receiving of cooling fluid is depicted using white arrows.

For example, assume the two shaded-in objects (shaded using different in-fill patterns) represent portions of cooling tubes 108 that lead away from chassis 112 and toward the manifold. The white arrows that overlap cooling tubes 108 may indicate a general direction in which cooling fluid flows within the tubular structures of cooling tubes 108.

For example, the darker shaded object of cooling tubes 108 may represent cooling fluid that has not been heated. Therefore, a general directional flow of the cooling fluid that flows through the darker shaded object is depicted with left-pointing arrows to indicate that the cooling fluid is being provided to chassis 112, from vertical tube 210.

The lighter shaded object of cooling tubes 108 may represent heated cooling fluid. Therefore, a general directional flow of the cooling fluid that flows through the lighter shaded object is depicted with right-pointing arrows to indicate that the cooling fluid is being received by the manifold (e.g., received by vertical tube 209).

As previously mentioned, to establish fluid communication between chassis 112 and the manifold, quick connections 206 may be used. Quick connections 206 may allow for a chassis such as chassis 112 to be positioned with rack system 200 such that a chassis port (not explicitly shown in FIG. 2B) of chassis 112 is secured (e.g., sealed) to a port of the manifold that allows for cooling fluid to flow through manifold wall 232 and into chassis 112.

For example, a quick connection of quick connections 206 may be implemented using a compression tube connection type, and thus, may also be referred to as a quick-disconnect (QD) socket. This compression tube connection type may be implemented by pushing the chassis port and the port of the manifold against one another. By doing so, pressure may be applied to the QD socket. Once a pressure threshold is exceeded by this applied pressure, the connection may be successfully made, and the fluid communication may be established.

For example, due to the stationary position of the manifold with respect to rack system 200 (e.g., at the rear of the rack system), chassis 112 may be aligned with a rack of the rack system and pushed toward the rear of the rack system such that a chassis port positioned on a rear of chassis 112 is moved toward an aligned port of the manifold as chassis 112 is pushed. Chassis 112 may continue to be pushed until positioned in a predetermined location. While in this predetermined location, an amount of additional force (e.g., to exceed the pressure threshold) may be required to secure attachment between the two ports, thereby sealing the QD socket with the chassis port.

Connection and/or disconnection of a QD socket may be manually facilitated. For example, connection and/or disconnection of a QD socket may be facilitated by a technician. However, assume a scenario in which the technician is not on site (e.g., is a significant distance away from the rack system such that the technician may not be able to prevent the hardware components from being negatively impacted by a leak).

Therefore, in this scenario, if a leak occurs and the technician is not available to sever the fluid communication, the manifold may continue to provide the cooling fluid to a chassis that houses the leak. Consequently, liquid may continue to enter an interior of the chassis, thereby increasing a likelihood of compromising (and/or otherwise negatively impacting) functionality of the hardware components.

To decrease the likelihood if negatively impacting the functionality of the hardware components (e.g., should a leak occur), a fluid management mechanism (e.g., 214, discussed below with regard to FIG. 2C) may be used to allow for the fluid communication to be severed and/or established without facilitation (e.g., by a direct/physical means) by, for example, the technician.

Thus, to manage the fluid communication, the rack system may include the fluid management mechanism, discussed further below with regard to FIGS. 2C-2G.

In FIGS. 2C-2G, diagrams of fluid management mechanism 214 are shown in accordance with an embodiment. These diagrams may be used to discuss an example implementation of the fluid management mechanism while depicting the fluid management mechanism from multiple viewpoints.

Turning to FIG. 2C, a first diagram illustrating a fluid management mechanism (e.g., 214) in accordance with an embodiment is shown. The viewpoint of FIG. 2C may be a side view of chassis 112 mounted to rack system 200, similar to that of FIGS. 2A-2B, however, flipped horizontally. For example, in FIG. 2C, cooling tubes 108 may be positioned off of the right side of the page, and therefore, to the right of this first diagram depicting fluid management mechanism 214.

As previously mentioned with regard to FIG. 2B, to decrease the likelihood of negatively impacting the functionality of the hardware components (e.g., should a leak occur), fluid management mechanism 214 may be used to facilitate and/or prevent/sever fluid communication between a port of chassis 112 (e.g., chassis port 212) and the manifold (shown in FIG. 2C with vertical tube 210, vertical tube 210 being one of vertical tubes 208 shown in FIGS. 2A-2B and enclosed by manifold wall 232).

To do so, fluid management mechanism 214 (and/or rack system 200) may include horizontal tube 216 blind-mate connection plate 218, quick disconnect (QD) socket 220, rotating member 242, thread nut 244, redundant actuators 246, gears 248, and seal plate 230. Each of these is discussed below.

QD socket 220 may place chassis 112 in fluid communication with the manifold based on pressure applied against QD socket 220 by chassis port 212, the pressure needing to exceed a pressure threshold for QD socket 220 to allow the connection. To provide its functionality, QD socket 220 may be implemented with a compression tube connection type (a quick connection), discussed previously with regard to quick connections 206 in FIG. 2B.

Additionally, QD socket 220 may be positioned with blind-mate connection plate 218 discussed further below. By being positioned with blind-mate connection plate 218, QD socket 220 may be limited to a range of motion along an axis perpendicular to vertical tube 210 when being physically pushed by chassis port 212 (such as when chassis 112 is in a predetermined position, e.g., while mounted on a rack of rack system 200, previously discussed). This limited range of motion may maintain an alignment of fluid management mechanism 214 such that chassis port 212 remains aligned with QD socket 220, and QD socket 220 remains aligned with a port of the manifold through which the cooling fluid may flow.

Horizontal tube 216 may be adapted to (i) be in fluid communication with the manifold, and (ii) move between two positions to facilitate repositioning of the quick connection (e.g., QD socket 220).

Therefore, horizontal tube 216 may be adapted to (i) allow fluid to flow from vertical tube 210 while fluid communication is established by, for example, QD socket 220, and (ii) slide a distance into at least a portion of a body of the manifold (e.g., partially slide into vertical tube 210), the distance slid being along the perpendicular axis.

For example, while the horizontal tube is in a first position of the two positions and the chassis is in the predetermined position, the horizontal tube may be in fluid communication with the quick connection, and while the horizontal tube is not in the first position and the chassis is in the predetermined position, the horizontal tube may not be in fluid communication with the quick connection.

To provide its functionality, horizontal tube 216 may be implemented using a hollow tubular structure positioned with blind-mate connection plate 218 such that these two components may move in unison. For example, repositioning blind-mate connection plate 218 a centimeter towards manifold wall 232 may cause horizontal tube 216 to reposition by sliding into the body of the manifold by the centimeter, horizontal tube 216 and blind-mate connection plate 218 repositioning simultaneously and in a same direction (e.g., along the perpendicular axis).

Blind-mate connection plate 218 may, in part, provide stability for fluid management mechanism 214 while (i) chassis port 212 is connecting to the manifold, (ii) chassis port 212 is disconnecting from the manifold, and/or (iii) chassis port 212 is being prevented from connecting/disconnecting to/from the manifold.

To provide its functionality, blind-mate connection plate 218 may be implemented using a plate-like structure positioned with QD socket 220 that has two flat, even surfaces (e.g., faces) on opposite sides of the plate-like structure. One such flat, face may be facing chassis 112 while chassis 112 is in the predetermined position (e.g., mounted on the rack of rack system 200, previously discussed) while the opposite side's flat, face may be facing manifold wall 232.

The one such flat, face may have a width that allows a side portion of blind-mate connection plate 218 (e.g., a side of fluid management mechanism 214, from which the viewpoint of FIG. 2C originates) to (i) extend a distance past the width of vertical tube 210 and that (ii) extends out toward the side (e.g., extending out of the page in FIG. 2C).

For a clarifying depicting of this side portion, refer to FIGS. 2D-2F.

This side portion of blind-mate connection plate 218 may include a fixedly secured thread nut 244 that provides a hole (i) that spans through the entire depth of the plate-like structure (e.g., through the one such flat, face and out the opposite side's flat, face) and (ii) through which at least a portion of a rotating member (e.g., 242), discussed further below, may rotate through. Thus, thread nut 244 may provide a threaded through-point for rotating member 242, rotating member 242, when rotated, causing movement of blind-mate connection plate 218 due to the fixedly secured nature of thread nut 244. To provide its functionality, rotating member 242 may be mechanically coupled to the horizontal tube, and thus, adapted to reposition the horizontal tube between the two positions.

For additional information regarding rotating member 242 and how its rotation causes repositioning of blind-mate connection plate 218, refer to FIGS. 2D-2E.

As mentioned above, rotating member 242 may rotate to reposition horizontal tube 216 (and therefore, blind-mate connection plate 218). To initiate this rotation, rotating member 242 may be actuated by, for example, gears 248 and/or redundant actuators 246, each of which is discussed below.

Gears 248 may be mechanically coupled to rotating member 242, and when actuated by redundant actuators 246, may in turn actuate rotating member 242 (thereby causing the rotation of rotating member 242). To provide its functionality, gears 248 may be implemented using, for example, mechanical gears.

Redundant Actuators 246 may be adapted to apply force to the rotating member that causes the rotating member to rotate in one of two directions. When rotating in a first of the two directions, the horizontal tube is moved toward the chassis while the chassis is in the predetermined position. When rotating in a second of the two directions the horizontal tube is moved away from the chassis while the chassis is in the predetermined position.

Redundant actuators 246 may cause actuation of, for example, gears 248 and/or rotating member 242 based on a control signal received from, for example, a management entity (discussed further below). To provide its functionality, redundant actuators 246 may be implemented by, for example, mechanically coupled motors (e.g., redundant servo motors).

Additionally, in some cases, redundant actuators 246 may include a first actuator and a second actuator. The first actuator and the second actuator are redundantly mechanically coupled to the rotating member to improve a likelihood of the rack system being able to stop occurrences of leaks of the cooling fluid from continuing, the second actuator being adapted to apply a force to the rotating member that causes the rotating member to rotate in the one of the two directions.

Seal plate 230 may prevent leaks between horizontal tube 216 and vertical tube 210 while allowing horizontal tube 216 to move along the perpendicular axis when blind-mate connection plate 218 is repositioned a distance along the perpendicular axis by rotating member 242.

To provide its functionality, seal plate 230 may be implemented using (i) a first sealing surface to seal the seal plate to vertical tube 210, and (ii) a second sealing surface to seal the seal plate to the sliding horizontal tube.

For additional information regarding seal plate 230, refer to FIG. 2G.

By providing the above functionalities, fluid management mechanism 214 (and/or rack system 200) may (i) establish and/or maintain connections allowing fluid communication between a fluid distribution system and liquid cooling systems and (ii) sever and/or prevent the connections based on identification of leaks of the liquid cooling systems within rack system 200. In doing so, data processing systems may be protected from damage caused by leaks automatically upon identification of the leaks.

For additional information regarding fluid management mechanism 214, continue to FIG. 2D, below.

Turning to FIG. 2D, a second diagram illustrating a fluid management mechanism (e.g., 214) in accordance with an embodiment is shown. The viewpoint of FIG. 2D may be a top-down view of chassis 112 while chassis 112 is in the predetermined position, a front side of chassis 112 facing the bottom of the page while a rear side of chassis 112 faces a top of the page.

As previously discussed with regard to FIG. 2C, to decrease the likelihood of negatively impacting the functionality of the hardware components (e.g., should a leak occur), a fluid management mechanism (e.g., 214) may be used to (i) establish/maintain, and/or (ii) prevent/sever, fluid communication between (i) a chassis (e.g., 112) mounted on a rack of a rack system (e.g., 200) and (ii) a manifold (e.g., vertical tube 210) of a fluid distribution system.

To do so, a rotating member (e.g., 242) of the fluid management mechanism may be actuated (e.g., rotated) to move a blind-mate connection plate (e.g., 218), and therefore, both a horizontal tube (e.g., 216) and a QD socket (e.g., 220) positioned with the blin-mate connection plate as shown in FIGS. 2D-2E.

For example, assume a technician prepares rack system 200 for a client desiring liquid cooling systems to be housed in each chassis (such as chassis 112 and chassis 204 in FIG. 2A) mounted on racks of the rack system. Due to the technician knowing that he/she will be a significant distance from the rack system for quite some time after this initial setup, the technician checks that there are no present leaks in the liquid cooling systems and utilizes fluid management mechanism 214 to connect a fluid distribution system (e.g., the manifold including vertical tube 210 enclosed by manifold wall 232) positioned at a rear of the rack system with each chassis.

Assume the technician places chassis 112 on one of the racks, thereby aligning chassis port 212 with QD socket 220. The technician may then push chassis 112 toward the rear of the rack system such that chassis 112 is positioned (e.g., secured) in the predetermined location (previously mentioned), as shown in FIG. 2D.

Additionally, due to there being no leaks in the liquid cooling systems, the technician may cause (e.g., via a terminal of the management entity and/or via another avenue that causes a control signal to be provided to fluid management mechanism 214) a control signal to be provided to fluid management mechanism 214 indicating that there are no leaks present in chassis 112. Once obtained, the control signal may cause actuation of rotating member 242. Such actuation may include, for example, a rotation of rotating member 242.

As shown in FIG. 2D, this rotation may be, for example, counterclockwise (shown using the black and white arrow depicted as partially overlapping and partially underneath rotating member 242).

Due to a shape of a threaded hole provided by thread nut 244 positioned with blind-mate connection plate 218, the counterclockwise rotation of rotating member 242 may force thread nut 244 (and therefore, blind-mate connection plate 218) to be repositioned closer to chassis 112. For example, this repositioning is indicated in FIG. 2D by two small, black arrows on either side of blind-mate connection plate 218.

Furthermore, due to the shape of the threaded hole, if the technician pushes chassis 112 after the control signal is obtained by fluid management mechanism 214 (and blind-mate connection plate 218 has already been repositioned closer to chassis 112), pressure caused by chassis port 212 pushing against QD socket 220 may not further reposition blind-mate connection plate 218 to move back toward the manifold. Nor may this pressure cause further rotation of rotating member 242 due to the mechanical coupling of, for example, redundant actuators 246 and/or gears 248 as discussed in FIG. 2C.

Instead, this pressure (depicted with a small, white arrow overlapping chassis port 212 and QD socket 220) may allow QD socket 220 to facilitate the fluid communication between chassis 112 and vertical tube 210. For example, this fluid communication is shown using a pattern infill within the borders of vertical tube 210, horizontal tube 216, QD socket 220, chassis port 212, and an arrow pointing toward a bottom of the page (e.g., to emphasize the cooling fluid's entry into chassis 112).

For additional information regarding a pressure threshold needed to be overcome by this pressure for the fluid communication to be facilitated by QD socket 220, refer back to FIG. 2B.

After some time has passed (e.g., 3 months), assume a cooling tube (e.g., a portion of 108 in FIGS. 1-2A) housed in chassis 112 may be disconnected from a liquid cooling block (e.g., 110 in FIGS. 1-2A) also housed in chassis 112. For example, this cooling tube may have been pulling away from the liquid cooling block since being prepared by the technician, and thus, the eventual disconnection being inevitable.

Based on this disconnection, a leak becomes present in chassis 112, discussed further below with regard to FIG. 2E.

Turning to FIG. 2E, a third diagram illustrating a fluid management mechanism (e.g., 214) in accordance with an embodiment is shown. The viewpoint of FIG. 2E may be a top-down view of chassis 112, similar to that of FIG. 2D.

As mentioned above, a leak may become present in chassis 112. A leak sensor positioned in the interior of chassis 112 may detect the leak, the leak sensor being adapted to detect leaks due to the cooling fluid. For example, this leak sensor may be operably connected to fluid management mechanism 214, and/or a controller that manages the fluid management mechanism (and/or, more specifically, redundant actuators 246 as shown in FIG. 2C), to cause a reversed actuation of rotating member 242 when a leak is present. Thus, rotating member 242 may be rotated in a reversed direction as that described in FIG. 2D.

For example, this reversed rotation may be clockwise rather than the counterclockwise direction of the initiate rotation. For example, this reversed rotation is shown using the black and white arrow depicted as partially overlapping and partially underneath rotating member 242 in FIG. 2E.

Due to the shape of the threaded hole provided by thread nut 244 positioned with blind-mate connection plate 218, the clockwise rotation of rotating member 242 may force thread nut 244 (and therefore, blind-mate connection plate 218) to be repositioned further away from chassis 112. For example, this further repositioning is indicated in FIG. 2E by two small, black arrows on either side of blind-mate connection plate 218, the further repositioning being possible due to horizontal tube 216's and seal plate 230's functionality, discussed previously and further below with regard to FIGS. 2F-2G.

In doing so, the pressure between chassis port 212 and QD socket 220 may be lessened and/or removed entirely, thereby causing the pressure threshold (that when exceeded allows QD socket 220 to facilitate the fluid communication) to no longer be exceeded. Thus, QD socket 220 may cease facilitation of the fluid communication between chassis 112 and vertical tube 210.

For example, this severance (and/or prevention) of the fluid communication is shown using a pattern infill within the borders of vertical tube 210 and horizontal tube 216, and a lack of the pattern in-fill within the borders of QD socket 220 and chassis port 212 (e.g., to emphasize the cooling fluid being prevented from passing through QD socket 220).

For additional information regarding a pressure threshold needed to be overcome by this pressure for the fluid communication to be facilitated by QD socket 220, refer back to FIG. 2B.

It will be appreciated that if the leak is detected before fluid communication has been established, then the shape of the threaded hole may also prevent movement of blind-mate connection plate 218 toward chassis 112, thereby preventing connection between QD socket 220 and chassis port 212, and thus, preventing the fluid communication from being established/reestablished.

It will be further appreciated, assuming the leak is repaired and there is, once again, no leak present in chassis 112, that the actuation described in FIG. 2D to establish the fluid communication may occur again. This repeated actuation may also, in some cases, be followed by a reversed actuation as described in FIG. 2E. For example, this repeated reversed actuation may occur due to manual intervention utilizing control signals and/or based on leak detections. Thus, actuation and/or reversed actuation of rotating member 242 may reoccur for any number of repetitions.

Turning to FIG. 2F, a fourth diagram illustrating a fluid management mechanism (e.g., 214) in accordance with an embodiment is shown.

The viewpoint of FIG. 2F may be a front view of the fluid management mechanism (e.g., a front view of 214). For example, a front of fluid management mechanism 214 (that faces a same direction as the front side of chassis 112, as depicted in FIGS. 2D-2E) may face out of the page while a rear of fluid management mechanism 214 faces into the page.

It will be appreciated that the viewpoint shown in FIG. 2F may be a same view as that faced by a receiving end of chassis port 212 while chassis 112 is pushed toward the rear of the rack system.

The one such flat face of blind-mate connection plate 218 positioned with QD socket 220 and horizontal tube 216, as shown in FIG. 2F, may prevent pressure from being disproportionately applied across a surface of blind-mate connection plate 218 (e.g., may prevent disproportionate force from being applied on chassis port 212 when there is pressure between chassis port 212 and QD socket 220.

In doing so, a smooth repositioning of blind-mate connection plate 218 (and therefore, simultaneous smooth movement of respective components positioned with blind-mate connection plate 218) may be guided by rotating member 242's rotation within the threaded hole of thread nut 244 (e.g., and in some cases, guide rods like guide rod 223) along an axis (e.g., into and/or out of the page). In doing so, for example, connection to the chassis may be either facilitated or severed (and thus, the fluid communication may be respectively facilitated or severed). Additionally, in doing so, movement of horizontal tube 216 may be allowed through a manufactured breach in manifold wall 232 (e.g., made possible by functionality provided by seal plate 230, discussed below with respect to FIG. 2G).

Turning to FIG. 2G, a fifth diagram illustrating a fluid management mechanism (e.g., 214) in accordance with an embodiment is shown. The viewpoint of FIG. 2G may be an expanded top-down view of fluid management mechanism 214 that is similar to that of FIGS. 2D-2E but expanded to depict components of seal plate 230.

As previously discussed, seal plate 230 may be adapted to (i) seal the physical connection between the manifold (e.g., vertical tube 210) and horizontal tube 216, and to (ii) allow horizontal tube 216 to move with blind-mate connection plate 218 (e.g., even moving through manifold wall 232 via a manufactured breach that is managed by seal plate 230).

To do so, previously mentioned with regard to FIG. 2D, seal plate 230 may be implemented using (i) a first sealing surface to seal the seal plate to, for example, manifold wall 232, and (ii) a second sealing surface to seal the seal plate to horizontal tube 216. Each of these surfaces is discussed below.

To provide its functionality, the first sealing surface may include static seals 236. Static seals 236 may be implemented by sealing structures wedged between the first sealing surface and manifold wall 232. Such placement of static seals 236 may fixedly secure seal plate 230 to the manifold such that the first sealing surface remains undisturbed while horizontal tube 216 provides its own functionality involving movement along the previously mentioned perpendicular axis (e.g., to enter into at least a portion of an interior of vertical tube 210, housed by manifold wall 232).

To provide its functionality, the second sealing surface may include gasket 238 positioned between the second sealing surface and horizontal tube 216. Gasket 238 may be implemented by, for example, a gasket adapted to prevent cooling fluid from escaping an interior of vertical tube 210 and/or horizontal tube 216. For example, as the cooling fluid flows through vertical tube 210, into horizontal tube 216, and (while in fluid communication) through chassis port 212 (shown in FIGS. 2D-2E), gasket 238 may be adapted to prevent leakage while also not preventing the movement of horizontal tube 216 along the perpendicular axis. For example, if a structure such as static seal 236 were to replace gasket 238, the movement along the perpendicular axis would be prevented.

Thus, as discussed with regard to FIGS. 2C-2G, the fluid management mechanism (214) may mitigate and/or prevent damage to a system made possible due to presence of liquid used in the system (e.g., provided by a fluid distribution system for liquid cooling) by managing fluid communication within the system. In doing so, the likelihood of negatively impacting hardware functionality (e.g., due to leaked liquid within the system) may be decreased. Therefore, the likelihood of negatively impacting computer implemented services provided by the system may also be decreased.

While illustrated in FIGS. 2A-2G with a limited number of specific components, a system may include additional, fewer, and/or different components without departing from embodiments disclosed herein.

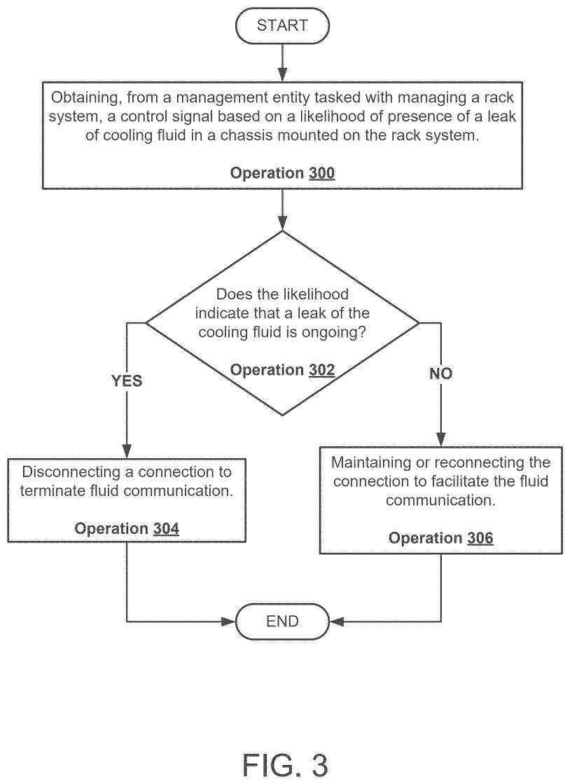

As discussed above, the components of FIGS. 2A-2G may facilitate and/or perform various functionalities to manage data processing systems. FIG. 3 illustrates methods that may be facilitated and/or performed by the components of FIG. 2A-2G.

In the diagram discussed below and shown in FIG. 3, any of the operations may be repeated, performed in different orders, and/or performed in parallel with or in a partially overlapping in time manner with other operations.

Turning to FIG. 3, a flow diagram illustrating a method for managing fluid communication of a data processing system by, for example, using a fluid management mechanism in accordance with an embodiment is shown. The method may be facilitated and/or performed, at least in part, for example, by the fluid management mechanism of a rack system (e.g., 200) and/or any other entity.

At operation 300, a control signal is obtained from a management entity tasked with managing a rack system based on a likelihood of presence of a leak of cooling fluid in a chassis mounted on the rack system. This control signal may be obtained by using a sensing functionality, for example, of the rack system.

For example, such a sensing functionality may be provided by (i) obtaining information indicating the presence of the leak (e.g., obtaining distinctive patterns of sound that escaping fluid is known to produce, obtaining pressure changes within a loop of the liquid cooling system through which cooling fluid flows, proximate traversal of the cooling fluid passed the leak sensor, etc.), and (ii) providing this information to, for example, the management entity (e.g., and/or an otherwise controller of the disconnection mechanism) of the data processing system via a data transmission that includes the information. This information that is provided to the management entity may, for example, indicate a likelihood of a leak being present in the chassis, the presence of the leak allowing cooling fluid to escape from a liquid cooling system at least partially housed by the chassis. The management entity may then, for example, send the control signal to the fluid management mechanism fluid management mechanism based on the likelihood (e.g., the control signal including data specifying the likelihood).

At operation 302, a determination may be made regarding whether the likelihood indicates that a leak of the cooling fluid is ongoing (e.g., a likelihood regarding whether the leak is currently present). This determination may be made by, for example, using an inference model trained to output such a determination based on an input that includes information such as the control signal provided by the management entity based on the likelihood.

For example, assume a first quantity of information (e.g., a number of the distinctive sound patterns) is obtained using the sensing functionality, the first quantity being above a danger threshold (e.g., a threshold for the information, the threshold used to differentiate between a first state of the rack system in which the leak is present and a second state of the rack system in which the leak is not present). Due to the first quantity of the information being above the danger threshold, the information provided to the management entity may indicate a high likelihood of the leak's presence in the chassis.

Alternatively, assume a second quantity of the information is obtained, the second quantity being below the danger threshold. Based on this second quantity, the information provided to the management entity may indicate a low likelihood of the leak's presence. Based on whether indicative of the high likelihood or the low likelihood, the control signal would be correspondingly indicative of the likelihood of the leak's presence.

Therefore, for example, when used as input for the inference model, the output may specify (e.g., based on the indicated state of the rack system) the presence of an ongoing leak based on the high likelihood, or specify no presence of an ongoing leak based on the low likelihood.

If determined that there is an ongoing presence of the leak, the method may continue to operation 304. Otherwise, the method may continue to 306.

At operation 304, a connection is disconnected to terminate fluid communication, the fluid communication being between a fluid distribution system of the rack system and the chassis. The connection may be disconnected by actuating (e.g., rotating) the rotating member, based on, for example, the output, such that the quick connection is moved away from the chassis and/or maintained a distance from the chassis (e.g., assuming the fluid communication was not established prior). This operation may be performed, for example, as discussed with regard to FIG. 2E. The method may end following operation 304.

Returning to operation 302, if determined that the leak is not present, the method may continue to operation 306.

It will be appreciated that although discussed at operation 304 with regard to the connection already being established at operation 302, the connection may instead be in a disconnected state at operation 302, and thus, may require reconnection should the leak not be present (e.g., as discussed with regard to operation 306 below).

At operation 306, the connection is maintained or reconnected to facilitate the fluid communication. This connection may be maintained or reconnected by reversibly actuating (e.g., rotating) the rotating member, based on, for example, the output, such that the quick connection is moved toward the chassis and/or maintained a distance from the chassis (e.g., the distance causing a pressure between a port of the chassis and the quick connection to be above a pressure threshold). This operation may be performed, for example, as discussed with regard to FIG. 2D.

The method may end following operation 306.

Thus, using the method illustrated in FIG. 3, embodiments disclosed herein may manage data processing systems while mitigating risks associated with using a liquid to facilitate such management. To do so, a fluid management mechanism may be used to control fluid communication between a fluid distribution system and, for example, data processing systems in a rack system.

In doing so, liquid used within the system that poses a threat to hardware functionality may be managed in a manner that decreases a likelihood of negatively impacting such functionality. Thus, a likelihood of negatively impacting hardware functionality of data processing systems may be decreased and may in turn decrease a likelihood of negatively impacting computer implemented services provided by the data processing systems.

The aforementioned method, and components described with respect to FIGS. 1-3, may be used with a data processing system to facilitate cooling of components of the data processing system while mitigating risk associated with using a liquid in the cooling process.

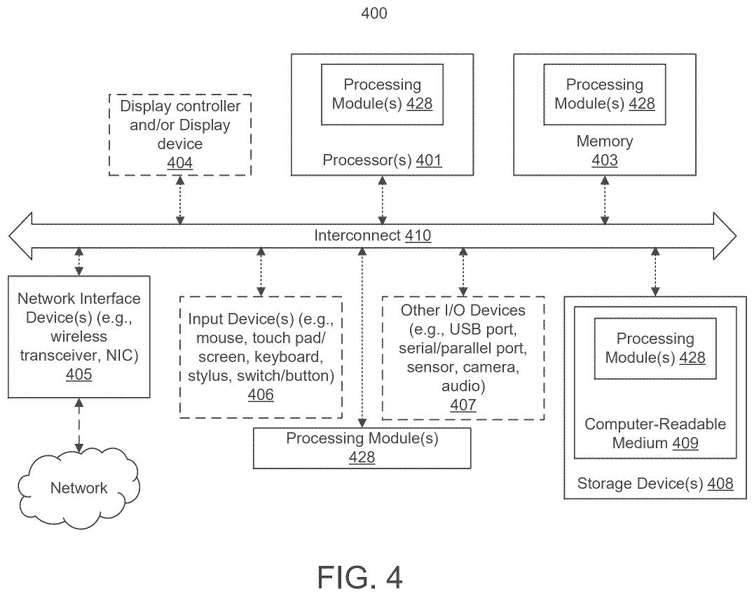

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A rack system, comprising:
a chassis adapted to house hardware components of a data processing system that provides computer implemented services;
a quick connection adapted to place the chassis in fluid communication with a manifold through which cooling fluid flows; and
a fluid management mechanism adapted to:
while the chassis is positioned in the rack system at a predetermined location:
reversibly reposition the quick connection with respect to the chassis to establish the fluid communication or terminate the fluid communication.

2. The rack system of claim 1, wherein the fluid management mechanism comprises:
a horizontal tube that:
is in fluid communication with the manifold; and
is adapted to move between two positions to facilitate repositioning of the quick connection.

3. The rack system of claim 2, wherein while the horizontal tube is in a first position of the two positions and the chassis is in the predetermined location, the horizontal tube is in fluid communication with the quick connection, and while the horizontal tube is not in the first position and the chassis is in the predetermined location, the horizontal tube is not in fluid communication with the quick connection.

4. The rack system of claim 2, wherein the fluid management mechanism further comprises:
a rotating member that is mechanically coupled to the horizontal tube to reposition between the two positions; and
an actuator adapted to apply force to the rotating member that causes the rotating member to rotate in one of two directions, when rotating in a first of the two directions the horizontal tube is moved toward the chassis while the chassis is in the predetermined location and when rotating in a second of the two directions the horizontal tube is moved away from the chassis while the chassis is in the predetermined location.

5. The rack system of claim 4, wherein the fluid management mechanism further comprises a second actuator adapted to apply a second force to the rotating member that causes the rotating member to rotate in the one of the two directions.

6. The rack system of claim 5, wherein the actuator and the second actuator are redundantly mechanically coupled to the rotating member to improve a likelihood of the rack system being able to stop occurrences of leaks of the cooling fluid from continuing.

7. The rack system of claim 1, wherein reversibly repositioning the quick connection comprises:
obtaining, from a management entity tasked with managing the rack system, a control signal based on a likelihood of presence of a leak of the cooling fluid in the chassis;
in a first instance of the obtaining where the likelihood indicates that a leak of the cooling fluid is ongoing:
disconnecting a connection to terminate the fluid communication; and
in a second instance of the obtaining where the likelihood indicates that a leak of the cooling fluid is not ongoing:
maintaining or reconnecting the connection to facilitate the fluid communication.

8. The rack system of claim 7, further comprising:
a leak sensor positioned in an interior of the chassis, adapted to detect leaks due to the cooling fluid, and operably connected to the management entity to activate an actuator when a leak is present.

9. The rack system of claim 1, further comprising:
A seal plate comprising:
A first sealing surface to seal the seal plate to a vertical tube and a second sealing surface to seal the seal plate to a slidable tube that connects the quick connection to the vertical tube.

10. The rack system of claim 1, wherein the cooling fluid flows through an interior of the chassis to cool a hardware component that contributes to the computer implemented services.

11. A system comprising:
a chassis adapted to house hardware components of a data processing system that provides computer implemented services;
a quick connection adapted to place the chassis in fluid communication with a manifold through which cooling fluid flows; and
a fluid management mechanism adapted to:
while the chassis is positioned in a rack system at a predetermined location:
reversibly reposition the quick connection with respect to the chassis to establish the fluid communication or terminate the fluid communication.

12. The system of claim 11, wherein the fluid management mechanism comprises:
a horizontal tube that:
is in fluid communication with the manifold; and
is adapted to move between two positions to facilitate repositioning of the quick connection.

13. The system of claim 12, wherein while the horizontal tube is in a first position of the two positions and the chassis is in the predetermined location, the horizontal tube is in fluid communication with the quick connection, and while the horizontal tube is not in the first position and the chassis is in the predetermined location, the horizontal tube is not in fluid communication with the quick connection.

14. The system of claim 12, wherein the fluid management mechanism further comprises:
a rotating member that is mechanically coupled to the horizontal tube to reposition between the two positions; and
an actuator adapted to apply force to the rotating member that causes the rotating member to rotate in one of two directions, when rotating in a first of the two directions the horizontal tube is moved toward the chassis while the chassis is in the predetermined location and when rotating in a second of the two directions the horizontal tube is moved away from the chassis while the chassis is in the predetermined location.

15. The system of claim 14, wherein the fluid management mechanism further comprises a second actuator adapted to apply a second force to the rotating member that causes the rotating member to rotate in the one of the two directions.

16. The system of claim 15, wherein the actuator and the second actuator are redundantly mechanically coupled to the rotating member to improve a likelihood of the rack system being able to stop occurrences of leaks of the cooling fluid from continuing.

17. The system of claim 11, wherein reversibly repositioning the quick connection comprises:
obtaining, from a management entity tasked with managing the rack system, a control signal based on a likelihood of presence of a leak of the cooling fluid in the chassis;
in a first instance of the obtaining where the likelihood indicates that a leak of the cooling fluid is ongoing:
disconnecting a connection to terminate the fluid communication; and
in a second instance of the obtaining where the likelihood indicates that a leak of the cooling fluid is not ongoing:
maintaining or reconnecting the connection to facilitate the fluid communication.

18. The system of claim 17, further comprising:
a leak sensor positioned in an interior of the chassis, adapted to detect leaks due to the cooling fluid, and operably connected to the management entity to activate an actuator when a leak is present.

19. The system of claim 11, further comprising:
A seal plate comprising:
A first sealing surface to seal the seal plate to a vertical tube and a second sealing surface to seal the seal plate to a slidable tube that connects the quick connection to the vertical tube.

20. The system of claim 11, wherein the cooling fluid flows through an interior of the chassis to cool a hardware component that contributes to the computer implemented services.
